(19) United States
(12) Patent Application Publication
(10) Pub. No.: US 2024/0006332 A1
(43) Pub. Date: Jan. 4, 2024

(54) FIDUCIAL MARKS FOR VERIFYING ALIGNMENT ACCURACY OF BONDED INTEGRATED CIRCUIT DIES

(71) Applicant: Intel Corporation, Santa Clara, CA (US)

(72) Inventors: Dimitrios Antartis, Hillsboro, OR (US); Nitin A. Deshpande, Chandler, AZ (US); Siyan Dong, Chandler, AZ (US); Omkar Karhade, Chandler, AZ (US); Gwang-soo Kim, Portland, OR (US); Shawna Liff, Scottsdale, AZ (US); Siddhartha Mal, Portland, OR (US); Debendra Mallik, Chandler, AZ (US); Khant Minn, Chandler, AZ (US); Haris Khan Niazi, Scottsdale, AZ (US); Arnab Sarkar, Chandler, AZ (US); Yi Shi, Chandler, AZ (US); Botao Zhang, Gilbert, AZ (US)

(73) Assignee: Intel Corporation, Santa Clara, CA (US)

(21) Appl. No.: 17/856,801

(22) Filed: Jul. 1, 2022

(51) Int. Cl. H01L 23/544; H01L 23/00; H01L 23/48

(52) U.S. Cl. CPC H01L 23/544; H01L 24/08; H01L 23/481; H01L 2224/08145; H01L 2223/54426

(57) ABSTRACT

An integrated circuit (IC) device comprises a host component and an IC die directly bonded to the host component. The IC die comprises a substrate material layer and a die metallization level between the substrate material layer and host component. The IC die includes an upper die alignment fiducial between the die metallization level and host component. The upper die alignment fiducial at least partially overlaps one or more metallization features within the die metallization level. In embodiments, at least two orthogonal edges of the upper die alignment fiducial do not overlap any of the metallization features within the die metallization level. In embodiments, the IC die includes a lower die alignment fiducial between the substrate material layer and the die metallization level. The lower die alignment fiducial may at least partially overlap one or more second metallization features within a second die metallization level of the IC die.

### BACKGROUND

In electronics manufacturing, integrated circuit (IC) packaging is a stage of the manufacturing process where an IC that has been fabricated on a die or chip comprising a semiconducting material is coupled to a supporting case or “package” that can protect the IC from physical damage and support electrical contacts suitable for further connecting to a host component, such as a printed circuit board (PCB). In the IC industry, the process of fabricating a package is often referred to as packaging, or assembly.

The IC industry is continually striving to produce higher computational performance in smaller packages for use in various electronic products, such as computer servers, portable computers, electronic tablets, desktop computers, and mobile communication handsets. High performance computing products often now include one or more microelectronic packages that contain various combinations of semiconductor tiles, chips, chiplets, and dies that are integrated into one functional unit. These composite, or heterogeneous, IC device structures may include tiles, chips, chiplets, or dies created using diverse technologies and materials. The tiles, chips, chiplets, or dies may be stacked vertically, placed horizontally, or both. Connections between different devices may employ a variety of technologies, including direct bonding.

There are a variety of manufacturing challenges at the IC packaging stage of electronics manufacturing. Some manufacturing challenges arise when an IC die is stacked vertically on or placed horizontally with another IC die in an IC package.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a cross-sectional view of an IC device comprising a host component having a lower host alignment fiducial and an IC die having a lower die alignment fiducial according to some embodiments;

FIG. 2 is a diagram illustrating a vector transformation to obtain post-bonding placement error according to some embodiments;

FIG. 3 is a cross-sectional view of an IC device comprising a host component and an IC die comprising an upper die alignment fiducial at least partially overlapping a metallization feature according to some embodiments;

FIG. 4A is a plan view of a part of the IC device of FIG. 3 illustrating edges of an upper die alignment fiducial and FIG. 4B is a diagram illustrating a box-in-box fiducial feature pattern according to some embodiments;

FIG. 5 is a cross-sectional view of an IC device depicting an example of optical system parameters for determining accurate detection of a feature of the IC device according to some embodiments;

FIG. 6 is a cross-sectional view of an IC device comprising a host component and an IC die comprising a die metallization layer, a second die metallization layer, and lower die alignment fiducial according to some embodiments;

FIG. 7 is a cross-sectional view of an IC device comprising an IC die and a host component comprising a plurality of through-silicon vias according to some embodiments;

FIG. 8 is a cross-sectional view of an IC device comprising an IC die and a host component comprising an upper host alignment fiducial and a second upper host alignment fiducial, wherein the IC die overlaps the upper host alignment fiducial according to some embodiments;

FIG. 9 is a cross-sectional view of an IC device comprising an IC die and a host component comprising an upper host alignment fiducial and a second upper host alignment fiducial, wherein the IC die overlaps the upper host alignment fiducial according to some embodiments;

FIG. 10 is a cross-sectional view of an IC device comprising an IC die and a host component comprising an upper host alignment fiducial and a second upper host alignment fiducial, wherein the IC die overlaps the upper host alignment fiducial according to some embodiments;

FIG. 11 is a plan view of a portion of a frame area for a wafer according to some embodiments;

FIG. 12 is a functional block diagram of an electronic computing device in accordance with various embodiments; and

FIG. 13 illustrates a mobile computing platform and a data server machine employing an IC device comprising an IC die and a host component, wherein the IC die may include an upper die alignment fiducial and a lower die alignment fiducial, and the host component may include an upper host alignment fiducial and a lower host alignment fiducial in accordance with various embodiments.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or functional changes may be made without departing from the scope of claimed subject matter. It should also be noted that directions and references (e.g., up, down, top, bottom, etc.) may be used merely to facilitate the description of features in the drawings and relationship between the features. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with each of the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. For example, in the context of materials, one material or structure disposed over or under another may be directly in contact or may have one or more intervening materials. Moreover, one material disposed between two materials may be directly in contact with the two materials or may have one or more intervening materials. In contrast, a first material or structure “on” a second material or structure is in direct contact with that second material/structure. Similar distinctions are to be made in the context of component assemblies where a first component may be “on” or “over” a second component.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

In the manufacture of IC device, one or more “device layers” are fabricated during front-end-of-line (FEOL) processing. Device layers include active or passive devices, or devices of both types. In some embodiments, the active devices are field effect transistors (FETs). Active and passive devices in a device layer are examples of “metallization features.” In addition, one or more “metallization layers” are fabricated during back-end-of line (BEOL) processing. Active and passive devices of a device layer are interconnected into circuitry with metal structures within one or more metallization layers. A metallization layer may comprise any number of metal structures separated by inter-layer dielectric (ILD) material. The metal structures in a metallization layer are examples of “metallization features.”

The IC package examples described herein may be manufactured, in part, with bonding techniques in which metal features embedded within an insulator of one IC die are directly fused to metal features embedded within an insulator of another die. Where both the metal features and the insulators are fused, the resultant composite structure comprises a hybrid bonded interface of both metallurgically interdiffused metals and chemically bonded insulators. Prior to bonding, each IC die may be fabricated in a monolithic process separate from that of the other IC die. As such, an IC die may utilize the same or different semiconductor device fabrication technologies as the IC die to which it is bonded. These bonding techniques may be referred to as “hybrid” or “direct” bonding.

There are a variety of challenges at the IC packaging stage of electronics manufacturing. Some manufacturing challenges arise when an IC die is stacked vertically on or placed horizontally with another IC die in an IC package. Direct bonding enables tighter pitches between interconnects on the surface of an IC die than the pitches used in traditional bonding methods. For example, pitches may be less than 9 μm. Failure to accurately align the electrically conductive interconnects on the respective IC die can result in an interconnect on a die not having sufficient contact with a corresponding interconnect of another die, resulting in a device that does not operate correctly or at all. Accordingly, the tighter die pitch used in direct bonding can require significantly higher placement accuracy during the bonding step of manufacturing as compared with traditional bonding methods.

To verify the accuracy of bonding alignment when direct bonding is employed, a post-bond inspection may be performed. The direct bond interface is at a first surface of an IC die and a first surface of another IC die, such as a wafer. Typically, the fiducials used for alignment of the IC die and wafer are at the direct bond interface, e.g., on the first surface of the IC die and the first surface of the wafer. While the fiducials may be on an outside or top layer, they could be in any of the first few layers adjacent to the outside surface layer. Bulk silicon is transparent at various wavelengths used in infrared (IR) imaging. After bonding, IR imaging at surfaces opposite the first surfaces of the IC die and wafer may be used to view the fiducials used for alignment. However, when an IC die is imaged from these opposite surfaces, a metallization level may partially or completely block the IR signal so that fiducials on the first surfaces cannot be captured. The degree of blockage depends on, among other things, the density of metal within the metallization level. Accordingly, direct measurement of placement accuracy is difficult or impossible.

Embodiments relate to fiducial marks for verifying alignment accuracy of bonded IC dies. As described further below, various examples of IC die may include features that enable the accuracy of bonding alignment to be verified.

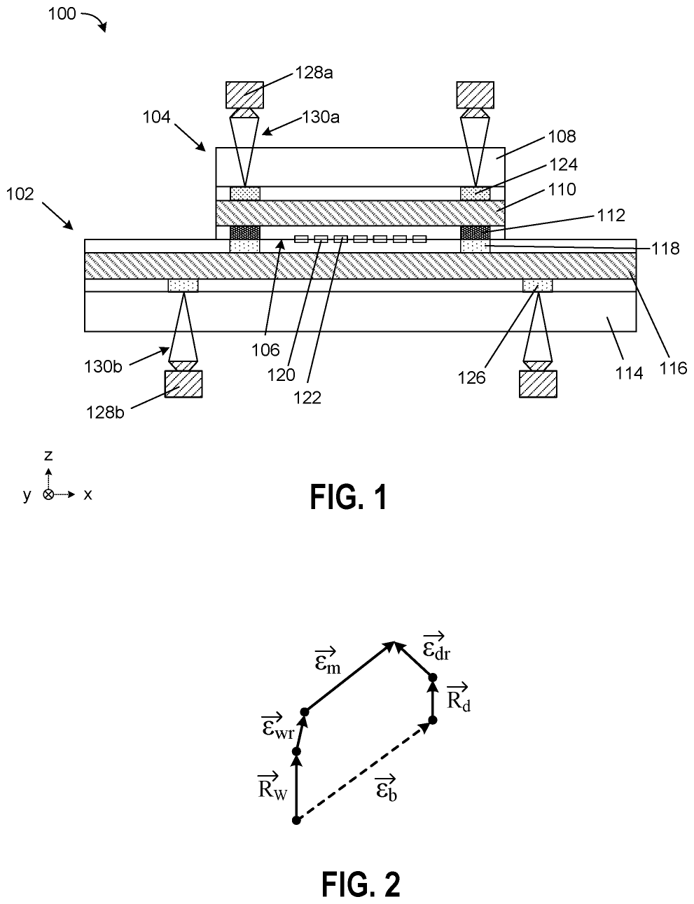

FIG. 1 is a cross-sectional view of an IC device 100 comprising a host component having a lower host alignment fiducial and an IC die having a lower die alignment fiducial according to some embodiments. As shown in FIG. 1, IC device 100 includes a host component 102 and an IC die 104 directly bonded to the host component at a bonding interface 106. In embodiments, the IC die 104 includes a substrate material layer 108, and a die metallization level 110 between the substrate material layer and the host component. In some embodiments, the substrate material layer 108 comprises predominantly silicon. The die metallization level 110 comprises one or more device layers and one or more metallization layers. An upper die alignment fiducial 112 is between the die metallization level 110 and the host component 102. In various embodiments, the upper die alignment fiducial 112 at least partially overlaps one or more metallization features within the die metallization level 110.

In embodiments, the host component 102 includes a second substrate material layer 114 and a host metallization level 116 between the second substrate material layer and the IC die 104. The host metallization level 116 comprises one or more device layers and one or more metallization layers. An upper host alignment fiducial 118 is between the host metallization level 116 and the IC die 104. In various embodiments, the upper host alignment fiducial 118 at least partially overlaps one or more metallization features within the host metallization level 116. The upper die alignment fiducial 112 and upper host alignment fiducial 118 may be used to align IC die 104 and host component 102 during a bonding process.

In various embodiments, host component 102 comprises an IC die, which may be referred to as a second IC die. In embodiments, the second substrate material layer 114 of the second IC die of host component 102 comprises predominantly silicon. In embodiments, one or more of the first IC die or second IC die comprise transistors. For example, die metallization level 110 or host metallization level 116 may include transistors. As mentioned, a metallization level is not the same as a metallization layer, e.g., die metallization level 110 comprises one or more device layers and one or more metallization layers.

Host component 102 includes one or more interconnect features 120 at bonding interface 106. Similarly, IC die 104 includes one or more interconnect features 122 at bonding interface 106. The interconnect features 120 and 122 may comprise metal contacts, pads, metallization features, or other interconnect structures on a surface of the IC die or host component. The interconnect features 120 and 122 in each of host component 102 and IC die 104 may be separated by a dielectric material. When host component 102 and IC die 104 are properly aligned, particular interconnect features 120 may contact corresponding features 122.

In various embodiments, IC die 104 includes a lower die alignment fiducial 124 between the substrate material layer 108 and the die metallization level 110. In addition, in some embodiments, the host component 102 includes a lower host alignment fiducial 126 between the second substrate material layer 114 and the host metallization level 116.

In various embodiments, lower die alignment fiducial 124 or lower host alignment fiducial 126, or both fiducials 124 and 126, are employed to verify alignment accuracy of bonded host component 102 and IC die 104. It may not be possible capture upper die alignment fiducial 112 or upper host alignment fiducial 118 with sufficient accuracy using IR imaging due to die metallization level 110 and host metallization level 116. Advantageously, lower die alignment fiducial 124 and lower host alignment fiducial 126 may be captured via IR imaging and used to verify alignment accuracy since the IR signal can penetrate substrate material layer 108 and second substrate material layer 114. In some embodiments, the respective positions of lower die alignment fiducial 124 and lower host alignment fiducial 126 can be near to device layers and lower metallization layers of die metallization level 110 or host metallization level 116 because an IR signal may, in some examples, be able to penetrate those layers due to the fact that metal thickness is very small and width of the signal narrow.

As shown in FIG. 1, a measuring tool 128a may project an IR signal 130a from above the IC device 100 into substrate material layer 108 at a backside (opposite bonding interface 106) of IC die 104. In additional, measuring tool 128b may project an IR signal 130b from below the IC device 100 into second substrate material layer 114 at a backside (opposite bonding interface 106) of host component 102. In embodiments, measuring tools 128a and 128b may be a transmission or reflection type IR system.

The positional relationship in the X-Y plane between the upper die alignment fiducial 112 and the lower die alignment fiducial 124 on IC die 104 is determined from design of the IC device 100 and by lithography registration accuracy. Similarly, the positional relationship in the X-Y plane between the upper host alignment fiducial 118 and the lower host alignment fiducial 126 on host component 102 is determined from design of the IC device 100 and by lithography registration accuracy. In some embodiments, these positional relationships can be measured before bonding to obtain the positional relationship parameters with greater precision than can be determined from the design and lithography registration accuracy. Only a few measurements are needed to establish these registration values because fiducials in the frame can establish the shift between a datum layer and a bond layer for every die in the interior of the frame. (The datum layer is a layer used as a common reference. Offsets may be measured from the datum layer to any layer of interest.) Measurement data can be fed forward via automation such that every die has a known registration vector between datum layer and bond layers.

FIG. 2 is a diagram illustrating a vector transformation to obtain post-bonding placement error \vec{ε_{b}}, which may be obtained using equation (1):

\vec{ε}_{b}=(\vec{R}_{w}+\vec{ε}_{wr})+\vec{ε}ₘ−(\vec{R}_{d}+\vec{ε}_{dr}) (1)

With respect to the upper host alignment fiducial 118 and the lower host alignment fiducial 126 of the host component 102, the lithography registration error between these fiducials is \vec{ε}_{wr}, and the positional relationship by design, i.e., the known theoretical vector, between these fiducials is \vec{R}_{w}. The vector \vec{ε}ₘ is the indirect IR measurement error between lower host alignment fiducial 126 of the host component 102 and lower die alignment fiducial 124 on IC die 104. With respect to the upper die alignment fiducial 112 and the lower die alignment fiducial 124 on IC die 104, the lithography registration error between these fiducials is \vec{ε}_{dr}, and the positional relationship by design, i.e., the known theoretical vector, between these fiducials is \vec{R}_{d}.

After bonding, IR post bond measurement can obtain the misalignment, corresponding with vector \vec{ε}ₘ, between lower host alignment fiducial 126 of the host component 102 and lower die alignment fiducial 124 on IC die 104. Based on the known positional relationship between the upper die alignment fiducial 112 and the lower die alignment fiducial 124 on IC die 104, and the known positional relationship in the X-Y plane between the upper host alignment fiducial 118 and the lower host alignment fiducial 126 on host component 102, the actual placement accuracy can be calculated, which is the misalignment between the upper die alignment fiducial 112 and the upper host alignment fiducial 118.

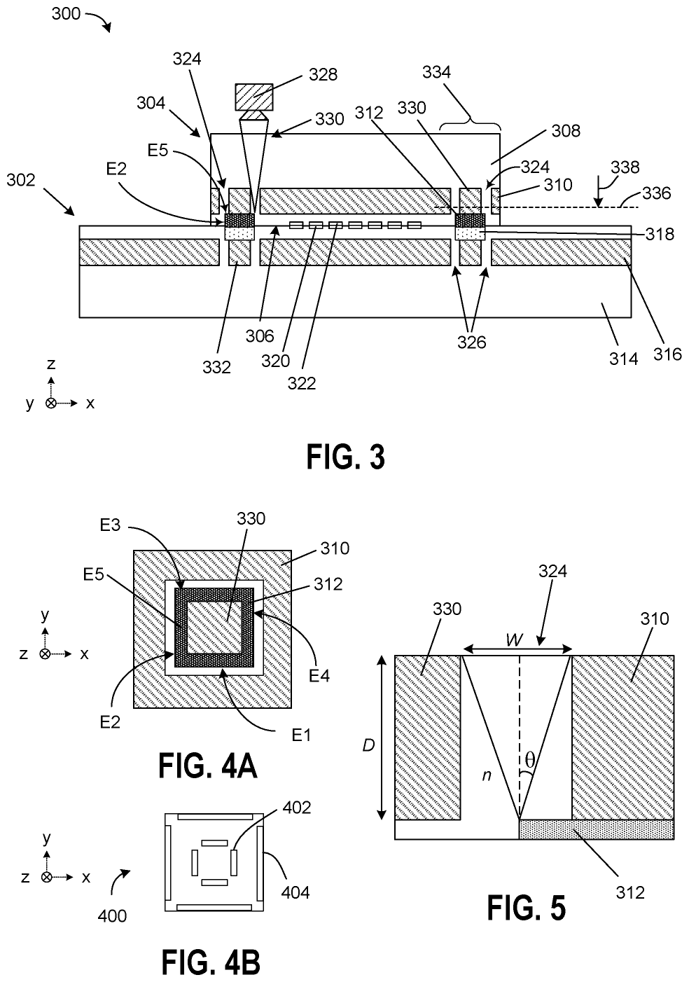

FIG. 3 is a cross-sectional view of an IC device 300 comprising a host component and an IC die having an upper die alignment fiducial at least partially overlapping a metallization feature according to some embodiments. As shown in FIG. 3, IC device 300 includes a host component 302 and an IC die 304 directly bonded to the host component 302 at a bonding interface 306. In embodiments, the IC die 304 includes a substrate material layer 308, and a die metallization level 310 between the substrate material layer 308 and the host component 302. In some embodiments, the substrate material layer 308 comprises predominantly silicon. The die metallization level 310 comprises one or more device layers and one or more metallization layers. An upper die alignment fiducial 312 is between the die metallization level 310 and the host component 302. In various embodiments, the upper die alignment fiducial 312 at least partially overlaps one or more metallization features within the die metallization level 310.

In embodiments, the host component 302 includes a second substrate material layer 314 and a host metallization level 316 between the second substrate material layer 314 and the IC die 304. The host metallization level 316 comprises one or more device layers and one or more metallization layers. An upper host alignment fiducial 318 is between the host metallization level 316 and the IC die 304. In various embodiments, the upper host alignment fiducial 318 at least partially overlaps one or more metallization features within the host metallization level 316. The upper die alignment fiducial 312 and upper host alignment fiducial 318 may be used to align IC die 304 and host component 302 during a bonding process. Advantageously, the upper die alignment fiducial 312 and upper host alignment fiducial 318 may also be used to verify alignment subsequent to the bonding process.

In various embodiments, host component 302 comprises an IC die, which may be referred to as a second IC die. In embodiments, the second substrate material layer 314 of the second IC die of host component 302 comprises predominantly silicon. In embodiments, one or more of the first IC die or second IC die comprise transistors. For example, die metallization level 310 or host metallization level 316 may include transistors.

Host component 302 includes one or more interconnect features 320 at bonding interface 306. Similarly, IC die 304 includes one or more interconnect features 322 at bonding interface 306. The interconnect features 320 and 322 may comprise metal contacts, pads, metallization features, or other interconnect structures on a surface of the IC die or host component. The interconnect features 320 and 322 in each of host component 302 and IC die 304 may be separated by a dielectric material. When host component 302 and IC die 304 are properly aligned, particular interconnect features 320 may contact corresponding features 322.

In various embodiments, as shown in FIG. 3, metallization level 310 of IC die 304 comprises one or more regions 324 that are substantially free of metallization features.

Region 324 may comprise predominately silicon in some embodiments. Regions 324 partially overlap with upper die alignment fiducial 312. In addition, each of the regions 324 partially overlap with an area adjacent (in the X-Y plane) to upper die alignment fiducial 312. In some embodiments, a region 324 may have a width (in the X-Y plane) of about 3-5 microns and a depth (in the Z plane) of about 10-15 microns. In contrast, upper die alignment fiducial 312 may have a width of about 10-15 microns. In other embodiments, region 324 and upper die alignment fiducial 312 may have different dimensions, depending on process or tool used. Accordingly, a region 324 exposes only an edge of an upper die alignment fiducial 312 (and an area adjacent to the edge), rather than the entire fiducial. While, in some embodiments, region 324 may completely overlap with upper die alignment fiducial 312 (exposing the entire fiducial), the partial overlap shown in FIG. 3 may be advantageous as it minimizes area of die metallization level 310 that is not used for metallization features. Another advantage is that a narrow region minimizes any impact on any planarization processes that may be performed, as compared with a more significant impact that may result from having a wide metal-free region.

Similar to die metallization level 310, host metallization level 316 comprises one or more regions 326 that are substantially free of metallization features. Region 326 may comprise predominately silicon in some embodiments. Regions 326 partially overlap with upper host alignment fiducial 318. In addition, each of the regions 326 partially overlap with an area adjacent (in the X-Y plane) to upper host alignment fiducial 318. In some embodiments, a region 326 may have a width (in the X-Y plane) of about 3-5 microns and a depth of about 10-15 microns. In contrast, upper host alignment fiducial 318 may have a width of about 10-15 microns. In other embodiments, region 326 and upper host alignment fiducial 318 may have different dimensions, depending on process or tool used. Accordingly, a region 326 exposes only an edge of an upper host alignment fiducial 318, rather than the entire fiducial. While, in some embodiments, region 326 may completely overlap with upper host alignment fiducial 318 (exposing the entire fiducial), the partial overlap shown in FIG. 3 may be advantageous as it minimizes area of host metallization level 316 that is not used for metallization features. In addition, another advantage is that a narrow region minimizes any impact on any planarization processes that may be performed, as compared with a more significant impact that may result from having a wide metal-free region.

Embodiments that include regions 324 or 326 require that a measuring tool using an IR signal only needs to capture the edge of a fiducial shape. Accordingly, the relatively narrow regions 324 or 326, each of which overlaps with one or more edges of a respective upper die or host alignment fiducial may be used to verify bonding alignment accuracy. As one example, measuring tool 328 may project an IR signal 330 from above the IC device 300 into substrate material layer 308 and one of the regions 324 at a backside of IC die 304. In some embodiments, there may be metallization features in various layers of metallization levels 310 and 316 beneath the upper die or host alignment fiducials. As can be seen in FIG. 3, metallization levels 310 and 316 include portions 330 and 332, respectively, that extend under upper die or host alignment fiducials 312 and 318. Metallization features may be placed in portions 330 and 332, provided the metallization features are generally within the boundary or “shadow area” of the fiducial shape. It should be appreciated that FIG. 3 is a cross-section that could be taken at most or all points along the Y-axis of IC device 300. In some embodiments, at one or more points along the Y-axis of IC device 300, portions 330 and 332 can extend in the X-axis direction to make a connection, respectively, with other portions of metallization levels 310 and 316. In these embodiments, regions 324 or 326 would not exist in a cross section taken at one or more points along the Y-axis. However, these points at which metallization levels 310 and 316 completely overlap fiducials 312 and 318 are relatively small, e.g., less than ten percent, in comparison to the entire edge in the Y-axis direction so that the portions do not prevent detection of the edge by a measuring tool using an IR signal.

FIG. 4A illustrates a plan view of a part of IC device 300 indicated by reference number 334, which includes portion 330 of die metallization level 310, other parts of die metallization level 310, and edges of one of the upper die alignment fiducials 312. The view in FIG. 4A is taken along line 336 in the direction of arrow 338 in FIG. 3, and assumes that substrate material layer 308 is transparent. As can be seen in FIG. 4A, upper die alignment fiducial 312 comprises four side edges: E1, E2, E3, and E4, which are in addition to a fifth backside edge E5 in the X-Y plane. Various adjacent side edges, e.g., E1 and E2, are substantially orthogonal to one another. In addition, side edges E1, E2, E3, and E4 are each substantially orthogonal to backside edge E5. It should be appreciated that upper host alignment fiducial 318, like upper die alignment fiducial 312, similarly comprises a plurality of side edges similar to side edges E1, E2, E3, and E4, and a backside edge which is substantially orthogonal to each side edge. Various adjacent side edges of upper host alignment fiducial 318 are substantially orthogonal to one another.

As can be seen in FIG. 4A, in some embodiments, at least two orthogonal edges of the upper die alignment fiducial 312 do not overlap any of the metallization features within the die metallization level 310. In addition, in some embodiments, at least two orthogonal edges of the upper host alignment fiducial 318 do not overlap any of the metallization features within the host metallization level 316.

FIG. 4B is a diagram illustrating a box-in-box fiducial feature pattern 400, which may include inner box features 402 and outer box features 404. In some embodiments, upper die alignment fiducial 312 may comprise inner box features 402 of box-in-box pattern 400. In addition, the upper surface of host component 302 at bonding interface 306 may comprise outer box features 404 of box-in-box pattern 400. The inner and outer box features 402, 404 may be placed at locations within a region 324 that is substantially free of metallization features, such that the features may be captured by a measuring tool using an IR signal. Similarly, in some embodiments, upper host alignment fiducial 318 may comprise inner box features 402 of box-in-box pattern 400. In addition, the upper surface of IC die 304 at bonding interface 306 may comprise outer box features 404 of box-in-box pattern 400. The inner and outer box features 402, 404 may be placed at locations within a region 326 that is substantially free of metallization features, such that the features may be captured by a measuring tool using an IR signal.

As shown in FIG. 3, in various embodiments, an IC device, e.g., IC device 300, includes regions in a metallization level that are substantially free of metallization features, e.g., regions 324, 326. Advantageously, these regions free of metallization features allow the accuracy of bonding alignment to be verified using fiducials at the bonding interface. FIG. 5 is a diagram depicting an example of parameters to be considered to ensure that the optical system of the measurement system has good visibility so that edges may be accurately detected.

The example of FIG. 5 illustrates part of the die metallization level 310 of IC die 304, including a portion 330 of the die metallization level 310 that extends under upper die alignment fiducial 312. To calculate an open area providing good visibility and edge detection, the numerical aperture (NA) of the optical system and the aspect ratio of the “well” opening must be considered. The NA of the optical system of the measurement system is given by Equation (2), which should be considered a general “rule of thumb.” The NA is a dimensionless number that characterizes the range of angles over which the optical system can accept or emit light. In Equation (2), n is the effective refractive index of the oxide layers the light propagates through, θ is the light collection angle, D is the thickness of impenetrable metal layers, and W is the width of the metal-free zone opening, e.g., regions 324, 326. As such, the NA is given by Equation (2):

$$NA = n sin ( θ ) = n sin ( {tan}^{- 1} ( \frac{W}{2 D} ) ) \qquad ( 2 )$$

The higher the objective used to image the fiducial edge, the larger the NA and hence the greater the light collection angle. If the aspect ratio remains constant, this would effectively cause clipping at the edges of the impenetrable metal layers of the die metallization level 310, thus leading to less light reaching the alignment fiducial 312, and the loss of high spatial frequency information, e.g. fiducial edges. Accordingly, the width W of the metal-free zone opening may require adjustment in some implementations.

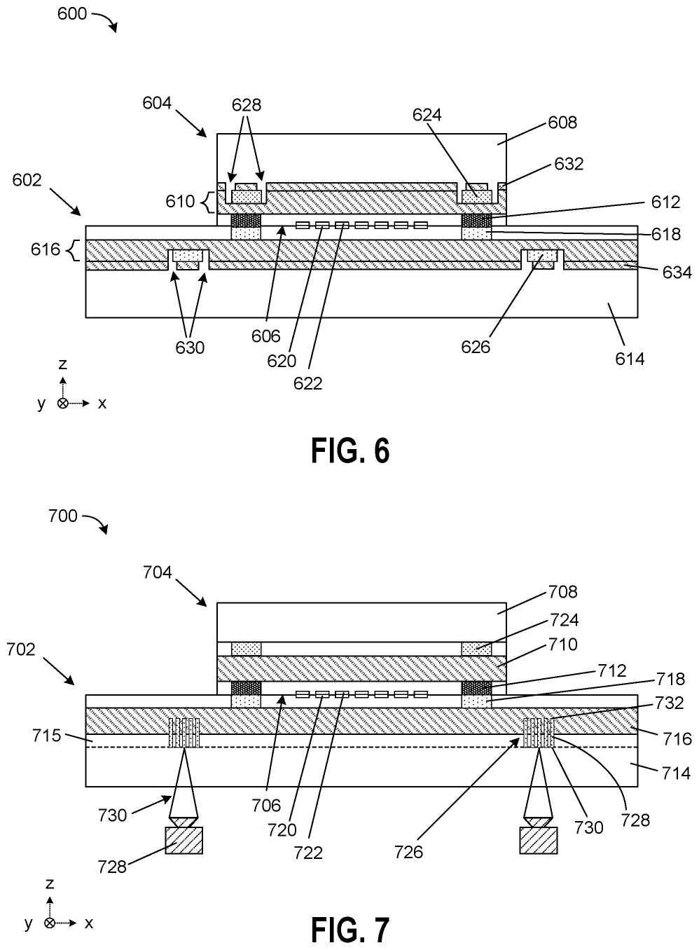

FIG. 6 is a cross-sectional view of an IC device 600 comprising a host component and an IC die comprising a die metallization level, a second die metallization level, and lower die alignment fiducial according to some embodiments. Embodiments described with reference to FIG. 1 include lower alignment fiducials that may be imaged with an IR measuring tool from the backside of an IC die, e.g., the lower die alignment fiducial 124 and a lower host alignment fiducial 126. In these embodiments, the lower alignment fiducials 124 and 126 may be on the lowest layer that can be penetrated by the IR signal of the measurement tool. Embodiments described with reference to FIG. 6 also include lower alignment fiducials similar to lower alignment fiducials 124 and 126, however, the lower alignment fiducials may be placed on a layer that would not be normally be able to be penetrated by the IR signal of the measurement tool. Placement on a higher layer than the embodiments of FIG. 1 advantageously allows for more design flexibility. The lower alignment fiducials may be placed on higher layers using techniques of embodiments described with respect to FIGS. 3-5, which include regions in a metallization level that are substantially free of metallization features, e.g., regions 324, 326 of FIG. 3. Regions free of metallization features 628, 630 may be used in embodiments described with reference to FIG. 6 provided they are sized so as to provide sufficient optical contrast. An additional advantage of these embodiments is that the lower alignment fiducials may fall within the same focal plane as upper alignment fiducials, which may allow measurements to be performed faster and with reduced errors.

As shown in FIG. 6, IC device 600 includes a host component 602 and an IC die 604 directly bonded to the host component at a bonding interface 606. In embodiments, the IC die 604 includes a substrate material layer 608, and a die metallization level 610 between the substrate material layer and the host component. In addition, IC die 604 includes a second die metallization level 632 between the substrate material layer 608 and die metallization level 610. In some embodiments, the substrate material layer 608 comprises predominantly silicon. Die metallization level 610 comprises one or more device layers and one or more metallization layers. Die metallization level 632 may comprise one or more device layers, one or more metallization layers, or both one or more device layers and one or more metallization layers. An upper die alignment fiducial 612 is between the die metallization level 610 and the host component 602. In various embodiments, the upper die alignment fiducial 612 at least partially overlaps one or more metallization features within the die metallization level 610.

In embodiments, the host component 602 includes a second substrate material layer 614 and a host metallization level 616 between the second substrate material layer 614 and the IC die 604. In addition, host component 602 includes a second host metallization level 634 between the second substrate material layer 614 and host metallization level 616. Host metallization level 616 comprises one or more device layers and one or more metallization layers. Host metallization level 634 may comprise one or more device layers, one or more metallization layers or both one or more device layers and one or more metallization layers. An upper host alignment fiducial 618 is between the host metallization level 616 and the IC die 604. In various embodiments, the upper host alignment fiducial 618 at least partially overlaps one or more metallization features within the host metallization level 616. The upper die alignment fiducial 612 and upper host alignment fiducial 618 may be used to align IC die 604 and host component 602 during a bonding process.

In various embodiments, host component 602 comprises an IC die, which may be referred to as a second IC die. In embodiments, the second substrate material layer 614 of the second IC die of host component 602 comprises predominantly silicon. In embodiments, one or more of the first IC die 604 or second IC die comprise transistors. For example, any of die metallization level 610, second die metallization level 632, host metallization level 616 or second host metallization level 634 may include transistors.

Host component 602 includes one or more interconnect features 620 at bonding interface 606. Similarly, IC die 604 includes one or more interconnect features 622 at bonding interface 606. The interconnect features 620 and 622 may comprise metal contacts, pads, metallization features, or other interconnect structures on a surface of the IC die or host component. The interconnect features 620 and 622 in each of host component 602 and IC die 604 may be separated by a dielectric material. When host component 602 and IC die 604 are properly aligned, particular interconnect features 620 may contact corresponding features 622.

In various embodiments, IC die 604 includes a lower die alignment fiducial 624 between the substrate material layer 608 and the die metallization level 610. In addition, in some embodiments, host component 602 includes a lower host alignment fiducial 626 between the second substrate material layer 614 and the host metallization level 616.

As described above, IC die 604 includes a second die metallization level 632. In embodiments, the second die metallization level 632 is between the substrate material layer 608 and the lower die alignment fiducial 624. In addition, the lower die alignment fiducial 624 at least partially overlaps one or more second metallization features within the second die metallization level 632.

As described above, host component 602 includes a second host metallization level 634. In embodiments, the second host metallization level 634 is between the second substrate material layer 614 and the lower host alignment fiducial 626. In addition, the lower host alignment fiducial 626 at least partially overlaps one or more second metallization features within the second host metallization level 634.

Metallization levels 610 and 632 of IC die 604 comprise one or more regions 628 that are substantially free of metallization features. Regions 628 may comprise predominately silicon in some embodiments. Lower portions of regions 628 partially overlap with lower die alignment fiducial 624. In addition, each of the regions 628 partially overlap with an area adjacent (in the X-Y plane) to lower die alignment fiducial 624. Similarly, metallization levels 616 and 634 of host component 602 comprise one or more regions 630 that are substantially free of metallization features. Regions 630 may comprise predominately silicon in some embodiments. Lower portions of regions 630 partially overlap with lower host alignment fiducial 626. In addition, each of the regions 630 partially overlap with an area adjacent (in the X-Y plane) to lower host alignment fiducial 626.

Embodiments that include regions 628 or 630 require that a measuring tool using an IR signal only needs to capture the edge of a fiducial shape. Accordingly, the relatively narrow regions 628 or 630, each of which overlaps with one or more edges of lower die alignment fiducial 624 or lower host alignment fiducial 626 may be used to verify bonding alignment accuracy.

FIG. 7 is a cross-sectional view of an IC device 700 comprising an IC die and a host component comprising a plurality of through-silicon vias (TSVs) according to some embodiments. Referring back to FIG. 1, some embodiments may include a lower die alignment fiducial 124 and a lower host alignment fiducial 126 that may be imaged with IR from the backside of an IC die. Embodiments described with reference to FIG. 7 are similar to embodiments described with reference to FIG. 1 in that the shown embodiment includes features that may be imaged with IR from the backside of an IC die or host component. In various embodiments described with reference to FIG. 7, a plurality of TSVs in the host component or IC die may be employed as a lower alignment fiducial. The plurality of TSVs may be arranged in an identifiable pattern which may serve as a lower alignment fiducial. In some embodiments, a plurality of through-dielectric vias (TDVs) may be used for the same purpose. In some implementations, the separation distance between layers of interest can add errors into the measurement. Accordingly, in some embodiments, an intermediate datum layer may be added to help to eliminate error contributions due to the distance between layers of interest.

As shown in FIG. 7, IC device 700 includes a host component 702 and an IC die 704 directly bonded to the host component at a bonding interface 706. In embodiments, the IC die 704 includes a substrate material layer 708, and a die metallization level 710 between the substrate material layer and the host component. In some embodiments, the substrate material layer 708 comprises predominantly silicon. The die metallization level 710 comprises one or more device layers and one or more metallization layers. An upper die alignment fiducial 712 is between the die metallization level 710 and the host component 702. In various embodiments, the upper die alignment fiducial 712 at least partially overlaps one or more metallization features within the die metallization level 710.

In embodiments, the host component 702 includes a second substrate material layer 714 and a host metallization level 716 between the second substrate material layer 714 and the IC die 704. A thickness of the second substrate material layer 714 is a third substrate material layer 715. As shown in FIG. 7, the third substrate material layer 715 is between the second substrate material layer 714 and host metallization level 716. In embodiments, the third substrate material layer 715 may be a distinct layer or part of the second substrate material layer 714. The host metallization level 716 comprises one or more device layers and one or more metallization layers. An upper host alignment fiducial 718 is between the host metallization level 716 and IC die 704. In various embodiments, the upper host alignment fiducial 718 at least partially overlaps one or more metallization features within host metallization level 716. The upper die alignment fiducial 712 and upper host alignment fiducial 718 may be used to align IC die 704 and host component 702 during a bonding process.

In various embodiments, host component 702 comprises an IC die, which may be referred to as a second IC die. In embodiments, the second substrate material layer 714 and third substrate material layer 715 of the second IC die of host component 702 comprises predominantly silicon. In embodiments, one or more of the first IC die 704 or second IC die comprise transistors. For example, die metallization level 710 or host metallization level 716 may include transistors.

Host component 702 includes one or more interconnect features 720 at bonding interface 706. Similarly, IC die 704 includes one or more interconnect features 722 at bonding interface 706. The interconnect features 720 and 722 may comprise metal contacts, pads, metallization features, or other interconnect structures on a surface of the IC die or host component. The interconnect features 720 and 722 in each of host component 702 and IC die 704 may be separated by a dielectric material. When host component 702 and IC die 704 are properly aligned, particular interconnect features 720 may contact corresponding features 722.

In various embodiments, the host component 702 comprises a plurality of TSVs 728, which may serve as a lower host alignment fiducial 726. Each of the of TSVs 728 includes a first end 730 and a second end 732. In some embodiments, lower host alignment fiducial 726 (TSVs 728) is between the second substrate material layer 714 and the host metallization level 716. In various embodiments, the plurality of TSVs 728 extend through a thickness of the second substrate material layer 714 corresponding with the third substrate material layer 715. As shown in FIG. 7, first ends 730 of TSVs 728 may be at second substrate material layer 714 and second ends 732 may be within host metallization level 716. In some embodiments, second ends 732 may be at or near an interface between host metallization level 716 and third substrate material layer 715. In some embodiments, TSVs 728 do not connect with circuitry in metallization level 716; in some embodiments, TSVs 728 connect with circuitry in metallization level 716. A measuring tool 728 may project an IR signal 730 from below the IC device 700 into host component 702.

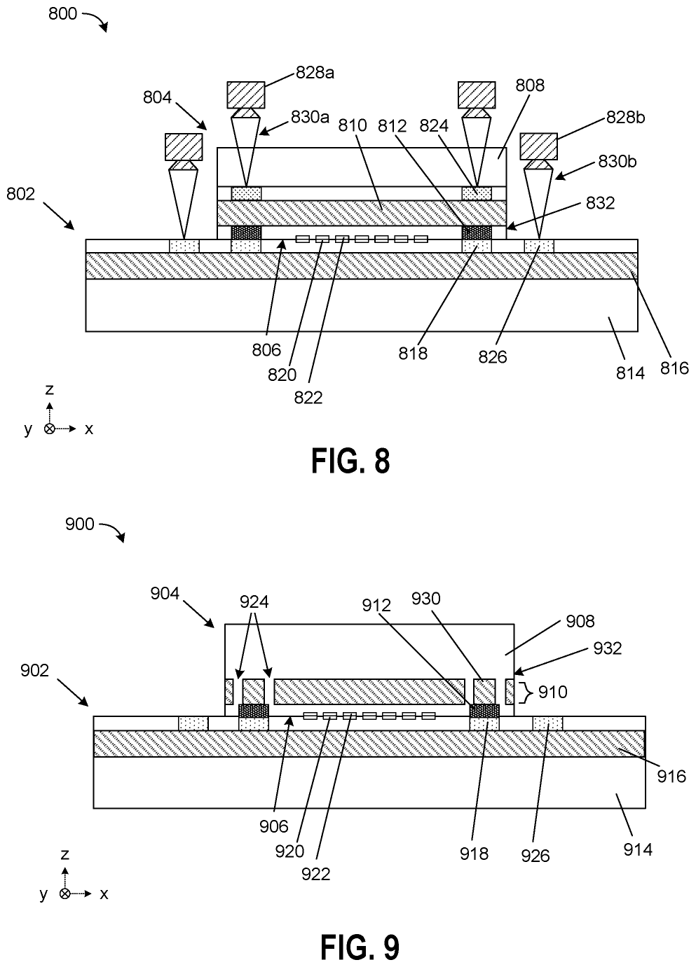

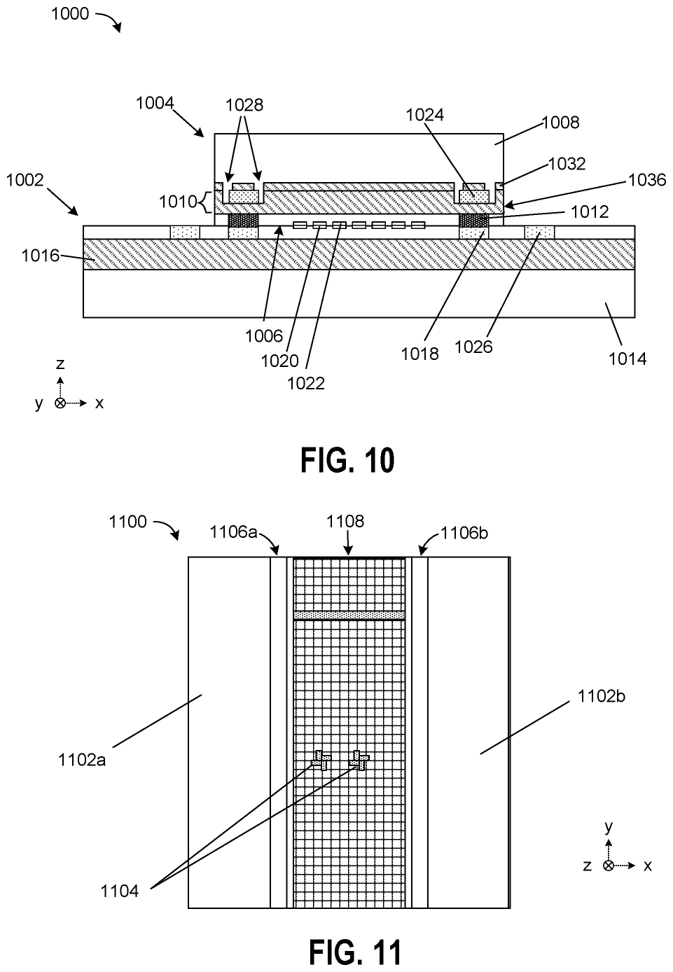

FIG. 8 illustrates a cross-sectional view of IC device 800, FIG. 9 a cross-sectional view of IC device 900, and FIG. 10 a cross-sectional view of IC device 1000. Each of the IC devices 800, 900, 1000 comprising a host component and an IC die in accordance with some embodiments. Some manufacturing processes use a metrology tool capable of performing measurements from both the die side and IC component side of an IC device. As can be seen in FIG. 1, measuring tool 128a projects an IR signal 130a from above the IC device 100 into IC die 104 and measuring tool 128b projects an IR signal 130b from below the IC device 100 into host component 102. However, other manufacturing processes use an IR metrology tool that lacks the capability to perform measurements from both sides of the IC device. IC devices 800, 900, 1000 may be used with an IR metrology tool capable of performing measurements from only side of the IC device.

IC devices 800, 900, 1000 provide one or more alignment fiducials on a top side of the host component, e.g., a wafer, outside of the footprint of the IC die stacked on the host component. These alignment fiducials may be imaged from above an IC device. The disclosed alignment fiducials may be used instead of alignment fiducials at the backside of the host component, e.g., lower host alignment fiducials 126, 626, and 726.

FIG. 8 is a cross-sectional view of IC device 800 comprising an IC die 804 and a host component 802 comprising an upper host alignment fiducial and a second upper host alignment fiducial, wherein the IC die overlaps the upper host alignment fiducial according to some embodiments. IC die 804 is directly bonded to the host component at a bonding interface 806. In embodiments, the IC die 104 includes a substrate material layer 808, and a die metallization level 810 between the substrate material layer and the host component. In some embodiments, the substrate material layer 808 comprises predominantly silicon. The die metallization level 810 comprises one or more device layers and one or more metallization layers. An upper die alignment fiducial 812 is between the die metallization level and the host component. In various embodiments, the upper die alignment fiducial 812 at least partially overlaps one or more metallization features within the die metallization level 810.

In embodiments, the host component 802 includes a second substrate material layer 814 and a host metallization level 816 between the second substrate material layer and the IC die 804. The host metallization level 816 comprises one or more device layers and one or more metallization layers. An upper host alignment fiducial 818 is between the host metallization level and the IC die. In various embodiments, the upper host alignment fiducial 818 at least partially overlaps one or more metallization features within the host metallization level 816. The upper die alignment fiducial 812 and upper host alignment fiducial 818 may be used to align IC die 804 and host component 802 during a bonding process.

In various embodiments, host component 802 comprises an IC die, which may be referred to as a second IC die. In embodiments, the second substrate material layer 814 of the second IC die of host component 802 comprises predominantly silicon. In embodiments, one or more of the first IC die or second IC die comprise transistors. For example, die metallization level 810 or host metallization level 816 may include transistors.

Host component 802 includes one or more interconnect features 820 at bonding interface 806. Similarly, IC die 804 includes one or more interconnect features 822 at bonding interface 806. The interconnect features 820 and 822 may comprise metal contacts, pads, metallization features, or other interconnect structures on a surface of the IC die or host component. The interconnect features 820 and 822 in each of host component 802 and IC die 804 may be separated by a dielectric material. When host component 802 and IC die 804 are properly aligned, particular interconnect features 820 may contact corresponding features 822.

In various embodiments, IC die 804 includes a lower die alignment fiducial 824 between the substrate material layer 808 and the die metallization level 810. In some embodiments, IC die 804 overlaps the upper host alignment fiducial 818, and host component 802 includes a second upper host alignment fiducial 826 that is beyond an edge of the IC die 804. For example, second upper host alignment fiducial 826 may be beyond edge 832. The second upper host alignment fiducial 826 may be on the surface of host component 802 that contacts IC die 804 but outside the footprint where IC die 804 contacts the host component.

A measuring tool 828a may project an IR signal 830a from above the IC device 800 into substrate material layer 808 at a backside (opposite bonding interface 806) of IC die 804. In addition, measuring tool 828b may project an IR signal 830b from above the IC device 800 at a front side of host component 802 beyond an edge of the IC die 804.

FIG. 9 is a cross-sectional view of IC device 900 comprising an IC die 904 and a host component 902 comprising an upper host alignment fiducial and a second upper host alignment fiducial, wherein the IC die overlaps the upper host alignment fiducial according to some embodiments. The IC die 904 is directly bonded to the host component 904 at a bonding interface 906. In embodiments, the IC die 904 includes a substrate material layer 908, and a die metallization level 910 between the substrate material layer and the host component. In some embodiments, the substrate material layer 908 comprises predominantly silicon. The die metallization level 910 comprises one or more device layers and one or more metallization layers. An upper die alignment fiducial 912 is between the die metallization level and the host component. In various embodiments, the upper die alignment fiducial 912 at least partially overlaps one or more metallization features within the die metallization level 910.

In embodiments, the host component 902 includes a second substrate material layer 914 and a host metallization level 916 between the second substrate material layer and the IC die 904. The host metallization level 916 comprises one or more device layers and one or more metallization layers. An upper host alignment fiducial 918 is between the host metallization level and the IC die. In various embodiments, the upper host alignment fiducial 918 at least partially overlaps one or more metallization features within the host metallization level 916. The upper die alignment fiducial 912 and upper host alignment fiducial 918 may be used to align IC die 904 and host component 902 during a bonding process.

In various embodiments, host component 902 comprises an IC die, which may be referred to as a second IC die. In embodiments, the second substrate material layer 914 of the second IC die of host component 902 comprises predominantly silicon. In embodiments, one or more of the first IC die or second IC die comprise transistors. For example, die metallization level 910 or host metallization level 916 may include transistors.

Host component 902 includes one or more interconnect features 920 at bonding interface 906. Similarly, IC die 904 includes one or more interconnect features 922 at bonding interface 906. The interconnect features 920 and 922 may comprise metal contacts, pads, metallization features, or other interconnect structures on a surface of the IC die or host component. The interconnect features 920 and 922 in each of host component 902 and IC die 904 may be separated by a dielectric material. When host component 902 and IC die 904 are properly aligned, particular interconnect features 920 may contact corresponding features 922.

In various embodiments, as shown in FIG. 9, metallization level 910 of IC die 904 comprises one or more regions 924 that are substantially free of metallization features. Region 924 may comprise predominately silicon in some embodiments. Regions 924 partially overlap with upper die alignment fiducial 912. In addition, each of the regions 924 partially overlap with an area adjacent (in the X-Y plane) to upper die alignment fiducial 912. In some embodiments, a region 924 may have a width (in the X-Y plane) of about 3-5 microns and a depth of about 10-15 microns. In contrast, upper die alignment fiducial 912 may have a width of about 10-15 microns. In other embodiments, region 924 and upper die alignment fiducial 912 may have different dimensions, depending on process or tool used. Accordingly, a region 924 exposes only an edge of an upper die alignment fiducial 912, rather than the entire fiducial. While, in some embodiments, region 924 may completely overlap with upper die alignment fiducial 912 (exposing the entire fiducial), the partial overlap shown in FIG. 9 may be advantageous as it minimizes area of die metallization level 910 that is not used for metallization features. In addition, a narrow region minimizes any impact on any planarization processes that may be performed, as compared with a more significant impact that may result from having a wide metal-free region.

Embodiments that include regions 924 require that a measuring tool using an IR signal only needs to capture the edge of a fiducial shape. Accordingly, the relatively narrow region 924, which overlaps with one or more edges of a respective upper die or host alignment fiducial may be used to verify bonding alignment accuracy. In some embodiments, there may be metallization features in various layers of metallization level 910 beneath the upper die alignment fiducial. As can be seen in FIG. 9, metallization level 910 include portions 930 that extends under upper die alignment fiducial 912. Metallization features may be placed in portion 930, provided the metallization features are within the boundary or “shadow area” of the fiducial shape.

In some embodiments, IC die 904 overlaps the upper host alignment fiducial 918, and host component 902 includes a second upper host alignment fiducial 926 that is beyond an edge of the IC die 904. For example, second upper host alignment fiducial 926 may be beyond edge 932 of IC die 904. of the IC die 804. For example, second upper host alignment fiducial 826 may be beyond edge 832. The second upper host alignment fiducial 926 may be 9 on the surface of host component 902 that contacts IC die 804 but outside the footprint where IC die 904 contacts the host component. A measuring tool (not shown) may project an IR signal from above IC device 900 at a front side of host component 902 beyond an edge of the IC die 804 to image second upper host alignment fiducial 926.

FIG. 10 is a cross-sectional view of IC device 1000 comprising an IC die 1004 and a host component 1002 comprising an upper host alignment fiducial and a second upper host alignment fiducial, wherein the IC die overlaps the upper host alignment fiducial according to some embodiments. The IC die 1004 is directly bonded to the host component at a bonding interface 1006. In embodiments, the IC die 1004 includes a substrate material layer 1008, and a die metallization level 1010 between the substrate material layer and the host component. In addition, IC die 1004 includes a second die metallization level 1032 between the substrate material layer 1008 and die metallization level 1010. In some embodiments, the substrate material layer 1008 comprises predominantly silicon. Die metallization level 1010 comprises one or more device layers and one or more metallization layers. Die metallization level 1032 may comprise one or more device layers, one or more metallization layers, or both one or more device layers and one or more metallization layers. An upper die alignment fiducial 1012 is between the die metallization level 1010 and the host component 1002. In various embodiments, the upper die alignment fiducial 1012 at least partially overlaps one or more metallization features within the die metallization level 1010.

In embodiments, the host component 1002 includes a second substrate material layer 1014 and a host metallization level 1016 between the second substrate material layer 1014 and the IC die 1004. Host metallization level 1016 comprises one or more device layers and one or more metallization layers. An upper host alignment fiducial 1018 is between the host metallization level 1016 and the IC die 1004. In various embodiments, the upper host alignment fiducial 1018 at least partially overlaps one or more metallization features within the host metallization level 1016. The upper die alignment fiducial 1012 and upper host alignment fiducial 1018 may be used to align IC die 1004 and host component 1002 during a bonding process.

In various embodiments, host component 1002 comprises an IC die, which may be referred to as a second IC die. In embodiments, the second substrate material layer 1014 of the second IC die of host component 1002 comprises predominantly silicon. In embodiments, one or more of the first IC die 1004 or second IC die comprise transistors. For example, any of die metallization level 1010, second die metallization level 1032, or host metallization level 1016 may include transistors.

Host component 1002 includes one or more interconnect features 1020 at bonding interface 1006. Similarly, IC die 1004 includes one or more interconnect features 1022 at bonding interface 1006. The interconnect features 1020 and 1022 may comprise metal contacts, pads, metallization features, or other interconnect structures on a surface of the IC die or host component. The interconnect features 1020 and 1022 in each of host component 1002 and IC die 1004 may be separated by a dielectric material. When host component 1002 and IC die 1004 are properly aligned, particular interconnect features 1020 may contact corresponding features 1022.

In various embodiments, IC die 1004 includes a lower die alignment fiducial 1024 between the substrate material layer 1008 and the die metallization level 1010.

As described above, IC die 1004 includes a second die metallization level 1032. In embodiments, the second die metallization level 1032 is between the substrate material layer 1008 and the lower die alignment fiducial 1024. In addition, the lower die alignment fiducial 1024 at least partially overlaps one or more second metallization features within the second die metallization level 1032.

Metallization levels 1010 and 1032 of IC die 1004 comprise one or more regions 1028 that are substantially free of metallization features. Regions 1028 may comprise predominately silicon in some embodiments. Lower portions of regions 1028 partially overlap with lower die alignment fiducial 1024. In addition, each of the regions 1028 partially overlap with an area adjacent (in the X-Y plane) to lower die alignment fiducial 1024. Embodiments that include regions 1028 require that a measuring tool using an IR signal only needs to capture the edge of a fiducial shape. Accordingly, the relatively narrow regions 1028, which overlaps with one or more edges of lower die alignment fiducial 1024 may be used to verify bonding alignment accuracy.

In some embodiments, IC die 1004 overlaps the upper host alignment fiducial 1018, and host component 1002 includes a second upper host alignment fiducial 1026 that is beyond an edge of the IC die 1004. For example, second upper host alignment fiducial 1026 may be beyond edge 1036. The second upper host alignment fiducial 1026 may be on the surface of host component 1002 that contacts IC die 1004 but outside the footprint where IC die 1004 contacts the host component 1002. A measuring tool (not shown) may project an IR signal from above IC device 1000 at a front side of host component 1002 beyond an edge of the IC die 1004 to image second upper host alignment fiducial 1026.

Advantageously, alignment of bonding of the embodiments depicted in FIGS. 8, 9, and 10 may be verified using an IR metrology tool capable of performing measurements from only side of the IC device. After bonding, the objective of the IR imaging tool needs to change position in the focal plane (Z coordinate position) and in the X and Y plane to obtain the relationship between a die backside fiducial (e.g., lower die alignment fiducials 824 and 1024) and wafer side fiducial (e.g., second upper host alignment fiducials 826 and 1026). However, changing positions in the focal plane and X-Y planes may each introduce additional measurement errors due to the mechanical error of the axes. As described below, a technique in which the position of the tool is static may be employed to eliminate this error.

In some embodiments, the wafer side fiducial may be placed close to the die backside fiducial so that both fiducials are in the same field of view (FOV) to eliminate the need for changing the X and Y positions of the objective of the measurement tool between measurements. For the host component (e.g., wafer), the relationship between wafer side fiducial (e.g., second upper host alignment fiducials 826 and 1026) and wafer frontside fiducial (e.g., upper host alignment fiducial 818 and 1018) is well known by design and measurement using registration techniques common to lithography in the frame. Since the wafer side fiducial and wafer frontside fiducial can be placed on the same layer, their actual relative position is accurate.

FIG. 11 is a plan view of a portion of a frame area for a wafer 1100. In the embodiments depicted in FIGS. 8, 9, and 10, second upper host alignment fiducials 826, 926, and 1026 are beyond an edge of an IC die. The second upper host alignment fiducial may be on (or near) the surface of host component but outside the footprint where IC die contacts the host component. Portions of dies 1102a, 1102c are separated by streets 1106a and 1106b, and frame 1108 are shown in FIG. 11. The second upper host alignment fiducials 826, 926, and 1026 may be a distinct feature 1104 in frame area 1108, such as “X”, box-in-box, or an object of another design. In addition, grating-based marks for the second upper host alignment fiducials 826, 926, and 1026 can be used directly as a wafer side fiducial other than specially designed fiducials. These marks may be eliminated in a final IC device.

It will be appreciated by one of ordinary skill in the art that the success and accuracy of detecting the fiducials disclosed herein depends on accurate detection of edges of the fiducial mark by an IR measuring tool, which depends on how contrast, sharpness, polarity, etc. of edges of the fiducial appear to the tool. Any background metal feature underneath the fiducial may significantly affect the measuring tools ability to accurately detect the fiducial. As one example, power rail structures under a fiducial may affect the ability of the IR measuring tool to accurately detect an edge of a fiducial. To address this problem, very fine metal features can be employed under the fiducial to provide a uniform background for fiducial detection. The small metal features may be a pattern, such as continuous fine metal lines, broken fine lines, fine grids, etc. The metal features may be of a size that is too small for IR optical system to resolve; the metal features may be of a size such that they will appear to the IR optical system as a uniform background. This technique may be referred to as “dummification.” In some embodiments, a fiducial may be located between a substrate layer and a metallization level comprising fine metal features below the fiducial. An advantage of providing fine metal features under the fiducial is that edges of the fiducial mark may be accurately detected. Therefore, no metal-free zone is need in the fiducial area. And transistors and metal routing can be added underneath the dummification layer without any impacts.

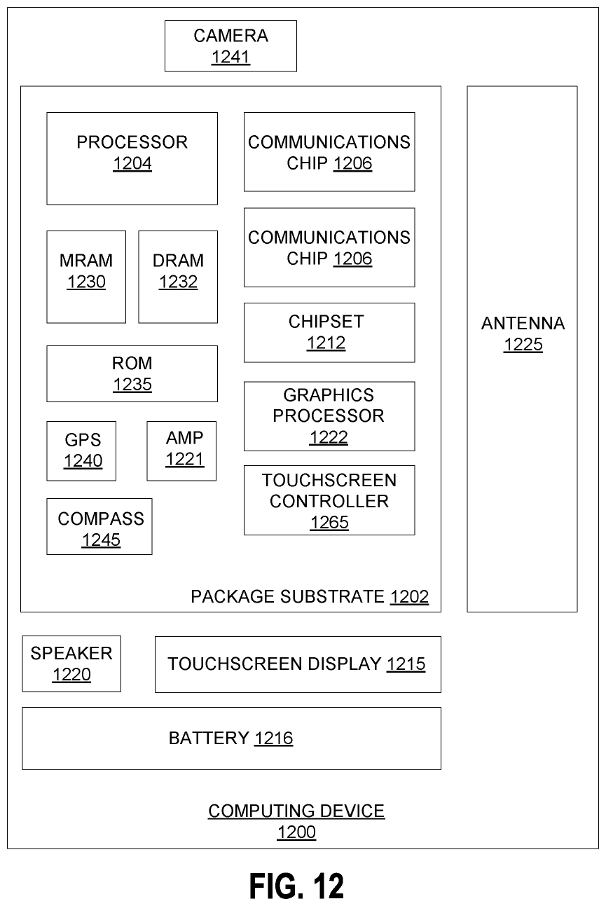

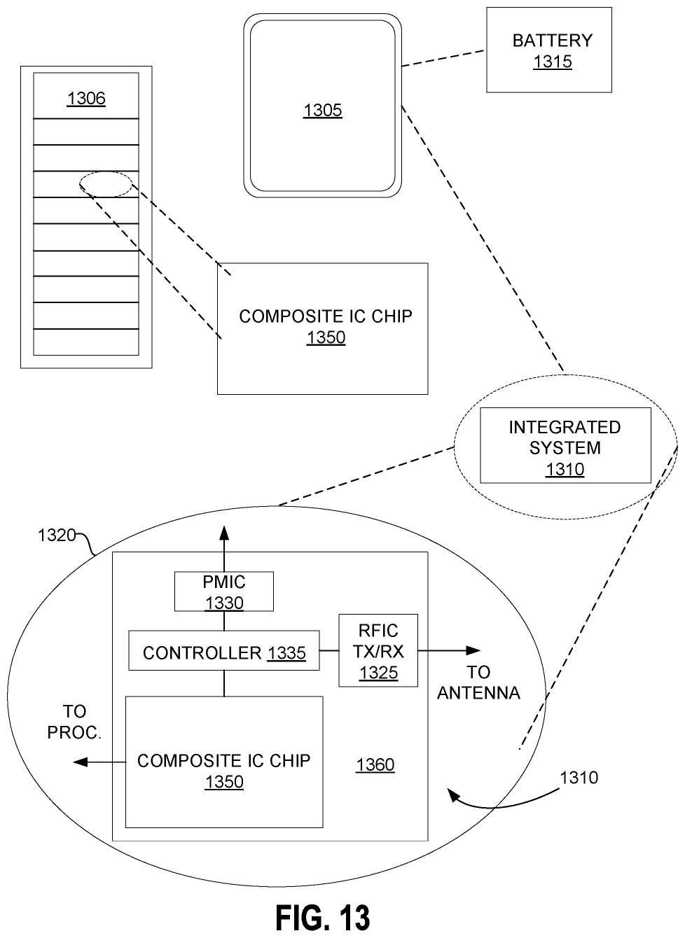

FIG. 12 is a functional block diagram of an electronic computing device 1200, in accordance with an embodiment. Device 1200 further includes a package substrate 1202 hosting a number of components, such as, but not limited to, a processor 1204 (e.g., an applications processor). Processor 1204 may be physically and/or electrically coupled to package substrate 1202. In some examples, processor 1204 is within a composite IC chip structure including a chiplet bonded to a host IC chip, for example as described elsewhere herein. Processor 1204 may be implemented with circuitry in either or both of the host IC chip and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 1206 may also be physically and/or electrically coupled to the package substrate 1202. In further implementations, communication chips 1206 may be part of processor 1204. Depending on its applications, computing device 1200 may include other components that may or may not be physically and electrically coupled to package substrate 1202. These other components include, but are not limited to, volatile memory (e.g., DRAM 1232), non-volatile memory (e.g., ROM 1235), flash memory (e.g., NAND or NOR), magnetic memory (MRAM 1230), a graphics processor 1222, a digital signal processor, a crypto processor, a chipset 1212, an antenna 1225, touchscreen display 1215, touchscreen controller 1265, battery 1216, audio codec, video codec, power amplifier 1221, global positioning system (GPS) device 1240, compass 1245, accelerometer, gyroscope, speaker 1220, camera 1241, and mass storage device (such as hard disk drive, solid-state drive (SSD), compact disk (CD), digital versatile disk (DVD), and so forth), or the like. In some exemplary embodiments, at two of the functional blocks noted above are within a composite IC chip structure including a chiplet bonded to a host IC chip, for example as described elsewhere herein. For example, processor 1204 be implemented with circuitry in a first of the host IC chip and chiplet, and an electronic memory (e.g., MRAM 1230 or DRAM 1232) may be implemented with circuitry in a second of the host IC chip and chiplet.

Communication chips 1206 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1206 may implement any of a number of wireless standards or protocols. As discussed, computing device 1200 may include a plurality of communication chips 1206. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

FIG. 13 illustrates a mobile computing platform and a data server machine employing an IC device comprising an IC die and a host component, wherein the IC die may include an upper die alignment fiducial and a lower die alignment fiducial, and the host component may include an upper host alignment fiducial and a lower host alignment fiducial, for example as described elsewhere herein. Computing device 1200 may be found inside platform 1305 or server machine 1306, for example. The server machine 1306 may be any commercial server, for example including any number of high-performance computing platforms disposed within a rack and networked together for electronic data processing, which in the exemplary embodiment includes a composite IC chip 1350 that includes a chiplet bonded to a host IC chip, for example as described elsewhere herein. The mobile computing platform 1305 may be any portable device configured for each of electronic data display, electronic data processing, wireless electronic data transmission, or the like. For example, the mobile computing platform 1305 may be any of a tablet, a smart phone, laptop computer, etc., and may include a display screen (e.g., a capacitive, inductive, resistive, or optical touchscreen), a chip-level or package-level integrated system 1310, and a battery 1315.

Whether disposed within the integrated system 1310 illustrated in the expanded view 1320, or as a stand-alone package within the server machine 1306, composite IC chip 1350 may include a chiplet bonded to a host IC chip, for example as described elsewhere herein. Composite IC chip 1350 may be further coupled to a host substrate 1360, along with, one or more of a power management integrated circuit (PMIC) 1330, RF (wireless) integrated circuit (RFIC) 1325 including a wideband RF (wireless) transmitter and/or receiver (TX/RX) (e.g., including a digital baseband and an analog front end module further comprises a power amplifier on a transmit path and a low noise amplifier on a receive path), and a controller 1335. PMIC 1330 may perform battery power regulation, DC-to-DC conversion, etc., and so has an input coupled to battery 1315 and with an output providing a current supply to other functional modules. As further illustrated, in the exemplary embodiment, RFIC 1325 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

In a first example, an integrated circuit (IC) device comprises: a host component and an IC die directly bonded to the host component. The IC die comprises: a substrate material layer and a die metallization level between the substrate material layer and the host component; and an upper die alignment fiducial between the die metallization level and the host component, wherein the upper die alignment fiducial at least partially overlaps one or more metallization features within the die metallization level.

In a second example, the IC device of example 1, wherein at least two orthogonal edges of the upper die alignment fiducial do not overlap any of the metallization features within the die metallization level.

In a third example, the IC device of example 1, wherein the IC die further comprises a lower die alignment fiducial between the substrate material layer and the die metallization level.

In a fourth example, the IC device of example 3, wherein the IC die further comprises a second die metallization level between the substrate material layer and the lower die alignment fiducial, and wherein the lower die alignment fiducial at least partially overlaps one or more second metallization features within the second die metallization level.

In a fifth example, the IC device of example 1, wherein the host component comprises: a second substrate material layer and a host metallization level between the second substrate material layer and the IC die; and an upper host alignment fiducial between the host metallization level and the IC die, wherein the upper host alignment fiducial at least partially overlaps one or more metallization features within the host metallization level.

In a sixth example, the IC device of example 5, wherein at least two orthogonal edges of the upper host alignment fiducial do not overlap any of the metallization features within the host metallization level.

In a seventh example, the IC device of example 5, wherein the host component further comprises a lower host alignment fiducial between the second substrate material layer and the host metallization level.

In an eighth example, IC device of example 7, wherein the host component further comprises a second host metallization level between the second substrate material layer and the lower host alignment fiducial, and wherein the lower host alignment fiducial at least partially overlaps one or more second metallization features within the second host metallization level.

In a ninth example, the IC device structure of example 7, wherein the lower host alignment fiducial further comprises: a plurality of through-silicon vias (TSVs), that extend through a thickness of the second substrate material layer.

In a tenth example, the IC device of example 5, wherein the IC die overlaps the upper host alignment fiducial, and wherein the host component further comprises a second upper host alignment fiducial that is beyond an edge of the IC die.

In an eleventh example, the IC device of example 1, wherein: the host component comprises a second IC die; the substrate material layer and second substrate material layer both comprises predominantly silicon; and one or more of the first IC die or second IC die comprise transistors.

In a twelfth example, the IC device of example 1, wherein the die metallization level comprises a zone that overlaps with at least two orthogonal edges of the upper die alignment fiducial and a region of the IC die adjacent to the upper die alignment fiducial, wherein the zone is substantially free of metallization features.

In a thirteenth example, the IC device of example 1, wherein a width of the zone is in a range of 3 to 5 microns.

In a fourteenth example, an integrated circuit (IC) device, comprising: a host component; and an IC die directly bonded to the host component, wherein the IC die comprises: a substrate material layer and a die metallization level between the substrate material layer and the host component; and an upper die alignment fiducial between the die metallization level and the host component, (solution 1, die side) wherein the IC die further comprises a lower die alignment fiducial between the substrate material layer and the die metallization level.

In a fifteenth example, the IC device of example 14, wherein the IC die further comprises a second die metallization level between the substrate material layer and the lower die alignment fiducial, and wherein the lower die alignment fiducial at least partially overlaps one or more second metallization features within the second die metallization level.

In a sixteenth example, IC device of example 14, wherein the IC die further comprises an upper die alignment fiducial between the die metallization level and the host component.

In a seventeenth example, the device of example 14, wherein the host component comprises: a second substrate material layer and a host metallization level between the second substrate material layer and the IC die; an upper host alignment fiducial between the host metallization level and the IC die, wherein the IC die overlaps the upper host alignment fiducial; and a second upper host alignment fiducial that is beyond an edge of the IC die.

In an eighteenth example, a system comprises: an integrated circuit (IC) device and a power supply. The IC device comprises: a host component; and an IC die directly bonded to the host component at a bonding interface, wherein the IC die comprises: a substrate material layer and a die metallization level between the substrate material layer and the host component; and an upper die alignment fiducial between the die metallization level and the bonding interface, wherein the upper die alignment fiducial at least partially overlaps one or more metallization features within the die metallization level. The power supply is coupled to provide power to the IC device.

In a nineteenth example, the system of example 18, wherein at least two orthogonal edges of the upper die alignment fiducial do not overlap any of the metallization features within the die metallization level.

In a twentieth example, the system of example 18, wherein the IC die further comprises a lower die alignment fiducial between the substrate material layer and the die metallization level.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should therefore be determined with reference to the appended claims, along with the full scope of equivalents to which such claims are entitled.

What is claimed is:

1. An integrated circuit (IC) device, comprising:
a host component; and
an IC die directly bonded to the host component, wherein the IC die comprises:
a substrate material layer and a die metallization level between the substrate material layer and the host component; and
an upper die alignment fiducial between the die metallization level and the host component, wherein the upper die alignment fiducial at least partially overlaps one or more metallization features within the die metallization level.

2. The IC device of claim 1, wherein at least two orthogonal edges of the upper die alignment fiducial do not overlap any of the metallization features within the die metallization level.

3. The IC device of claim 1, wherein the IC die further comprises a lower die alignment fiducial between the substrate material layer and the die metallization level.

4. The IC device of claim 3, wherein the IC die further comprises a second die metallization level between the substrate material layer and the lower die alignment fiducial, and wherein the lower die alignment fiducial at least partially overlaps one or more second metallization features within the second die metallization level.

5. The IC device of claim 1, wherein the host component comprises:
a second substrate material layer and a host metallization level between the second substrate material layer and the IC die; and
an upper host alignment fiducial between the host metallization level and the IC die, wherein the upper host alignment fiducial at least partially overlaps one or more metallization features within the host metallization level.

6. The IC device of claim 5, wherein at least two orthogonal edges of the upper host alignment fiducial do not overlap any of the metallization features within the host metallization level.

7. The IC device of claim 5, wherein the host component further comprises a lower host alignment fiducial between the second substrate material layer and the host metallization level.

8. The IC device of claim 7, wherein the host component further comprises a second host metallization level between the second substrate material layer and the lower host alignment fiducial, and wherein the lower host alignment fiducial at least partially overlaps one or more second metallization features within the second host metallization level.

9. The IC device structure of claim 7, wherein the lower host alignment fiducial further comprises:
a plurality of through-silicon vias (TSVs), that extend through a thickness of the second substrate material layer.

10. The IC device of claim 5, wherein the IC die overlaps the upper host alignment fiducial, and wherein the host component further comprises a second upper host alignment fiducial that is beyond an edge of the IC die.

11. The IC device of claim 1, wherein:
the host component comprises a second IC die;
the substrate material layer and second substrate material layer both comprise predominantly silicon; and
one or more of the first IC die or second IC die comprise transistors.

12. The IC device of claim 1, wherein the die metallization level comprises a zone that overlaps with at least two orthogonal edges of the upper die alignment fiducial and a region of the IC die adjacent to the upper die alignment fiducial, wherein the zone is substantially free of metallization features.

13. The IC device of claim 1, wherein a width of the zone is in a range of 3 to 5 microns.

14. An integrated circuit (IC) device, comprising:
a host component; and
an IC die directly bonded to the host component, wherein the IC die comprises:
a substrate material layer and a die metallization level between the substrate material layer and the host component; and
an upper die alignment fiducial between the die metallization level and the host component, (solution 1, die side) wherein the IC die further comprises a lower die alignment fiducial between the substrate material layer and the die metallization level.

15. The IC device of claim 14, wherein the IC die further comprises a second die metallization level between the substrate material layer and the lower die alignment fiducial, and wherein the lower die alignment fiducial at least partially overlaps one or more second metallization features within the second die metallization level.

16. The IC device of claim 14, wherein the IC die further comprises an upper die alignment fiducial between the die metallization level and the host component.

17. The IC device of claim 14, wherein the host component comprises:
a second substrate material layer and a host metallization level between the second substrate material layer and the IC die;
an upper host alignment fiducial between the host metallization level and the IC die, wherein the IC die overlaps the upper host alignment fiducial; and
a second upper host alignment fiducial that is beyond an edge of the IC die.

18. A system comprising:
an integrated circuit (IC) device, comprising:
a host component; and
an IC die directly bonded to the host component at a bonding interface, wherein the IC die comprises:
a substrate material layer and a die metallization level between the substrate material layer and the host component; and
an upper die alignment fiducial between the die metallization level and the bonding interface, wherein the upper die alignment fiducial at least partially overlaps one or more metallization features within the die metallization level; and
a power supply coupled to provide power to the IC device.

19. The system of claim 18, wherein at least two orthogonal edges of the upper die alignment fiducial do not overlap any of the metallization features within the die metallization level.

20. The system of claim 18, wherein the IC die further comprises a lower die alignment fiducial between the substrate material layer and the die metallization level.
